(19) United States
(12) Patent Application Publication
(10) Pub. No.: US 2025/0323081 A1
(43) Pub. Date: Oct. 16, 2025

(54) Vacuum Processing Apparatus

(71) Applicant: Hitachi High-Tech Corporation, Tokyo (JP)

(72) Inventors: Takumi NAGAYAMA, Tokyo (JP); Masaki Mizuochi, Tokyo (JP); Masashi Fujita, Tokyo (JP); Tomotaka Shibazaki, Tokyo (JP); Keiichiro Hosobuchi, Tokyo (JP)

(21) Appl. No.: 19/171,504

(22) Filed: Apr. 7, 2025

(30) Foreign Application Priority Data
Apr. 11, 2024 (JP) 2024-064007

(51) Int. Cl. H01L 21/68; H01L 21/687

(52) U.S. Cl. CPC H01L 21/681; H01L 21/68707

(57) ABSTRACT

There is provided a vacuum processing apparatus capable of accurately matching reference coordinates of a sample placement surface of a stage and center coordinates of a sample when a conveyance robot conveys the sample to a sample stage. The vacuum processing apparatus according to the present disclosure measures a position of an outer edge of the sample conveyed into a vacuum sample chamber, and moves a sample stage below the sample conveyed into the vacuum sample chamber based on the measured position of the outer edge.

### TECHNICAL FIELD

The present invention relates to a technique for transferring a sample to a sample stage using a conveyance robot in a vacuum processing apparatus.

### BACKGROUND ART

A vacuum processing apparatus used in processing and inspection of a semiconductor is strongly required to improve the number of wafers that can be processed per hour (hereinafter, throughput). Since a charged particle beam inspection apparatus emits a charged particle beam in a high vacuum environment, the wafer is conveyed from a preliminary exhaust chamber for connecting to an atmospheric pressure environment outside the apparatus to a sample chamber in a vacuum environment. Accordingly, it is possible to convey a sample wafer on an atmosphere side into the apparatus using the preliminary exhaust chamber while maintaining a high vacuum of the vacuum sample chamber, and it is possible to implement high throughput of the apparatus.

A conveyance robot including a hand is used to convey the sample wafer between the preliminary exhaust chamber and the vacuum sample chamber. When the sample wafer is conveyed by the conveyance robot, it is required to match center coordinates of the sample wafer with reference coordinates of a sample placement surface provided on a sample stage. In particular, in the charged particle beam inspection apparatus, when a distance between a ring-shaped electrode component provided around the sample placement surface and an outer edge portion of the sample wafer deviates from a target value determined by the apparatus, it becomes difficult to maintain a surface voltage of the outer edge portion of the sample wafer to be equal to a surface voltage of a center portion of the sample wafer, and a region (hereinafter, edge exclusion) in which accuracy of a surface shape measurement by the charged particle beam cannot be secured in the outer edge portion of the sample wafer increases. As a result, size control of a semiconductor device chip in the outer edge portion of the sample wafer cannot be performed similarly to size control of a chip in the center portion of the sample wafer, and a yield decreases.

By conveying the sample wafer to match the reference coordinates of the sample placement surface and the center coordinates of the sample wafer, the surface voltage of the outer edge portion of the sample wafer can be kept equal to the surface voltage of the center portion of the sample wafer. As a result, the edge exclusion is reduced, which contributes to improvement in the yield. For the above reasons, a technique for improving conveyance accuracy is required for the vacuum processing apparatus.

In general, there are three factors causing a decrease in the conveyance accuracy:
(1) Sliding occurred at a contact portion between the sample and the hand
(2) Thermal deformation of a component of the conveyance robot
(3) Change in a relative position between a conveyance start position and a conveyance target position

In the case of (1), as the robot operates, an inertial force is generated in a horizontal direction of a wafer surface at the contact portion between the sample and the hand. When the inertial force exceeds a frictional force of the contact portion between the sample and the hand, the sample slides and moves with respect to the hand and causes a conveyance error. Since the conveyance robot is disposed under a vacuum environment, it is difficult to implement a sample holding method using a pressure difference represented by vacuum suction. In addition, from the viewpoint of outgassing, it is difficult to mount a sensor for detecting the sliding.

In the case of (2), since the robot is disposed in a vacuum, there is no place for heat to escape, and a temperature of the component inside the robot rises due to repeated operations of the robot. As the temperature rises, the component inside the robot thermally expands, which causes a conveyance error.

In the case of (3), normally, in the vacuum processing apparatus including the preliminary exhaust chamber and the vacuum sample chamber, when the preliminary exhaust chamber and the vacuum sample chamber are sealed with a gate valve, since the preliminary exhaust chamber and the vacuum sample chamber are firmly connected to each other, an impact during opening and closing operations of a vacuum valve is transmitted to the vacuum sample chamber. In particular, in the case of the charged particle beam inspection apparatus, when vibration is transmitted into the vacuum sample chamber during a measurement operation using the charged particle beam, the measurement accuracy is reduced. Therefore, the measurement operation in the vacuum sample chamber is stopped while the vacuum valve is operated, and the operation of the vacuum valve is stopped while the measurement operation is performed in the vacuum sample chamber, thereby avoiding the decrease in the measurement accuracy. However, a stop of the processing and a stop of the operation of the valve in the vacuum sample chamber as described above lead to an increase in processing time per sample wafer, which causes a decrease in the throughput of the apparatus. On the other hand, when the preliminary exhaust chamber and the vacuum sample chamber are connected by a soft structure such as bellows, the vibration can be prevented, but a change in the relative position between the conveyance start position present in the preliminary exhaust chamber and the conveyance target position present in the vacuum sample chamber is caused.

PTL 1 discloses a configuration in which the bellows connects the preliminary exhaust chamber and the vacuum sample chamber, and the bellows absorbs the vibration generated by the opening and closing operations of the vacuum valve.

PTL 2 discloses, as a technique for ensuring the conveyance accuracy, a method of detecting an alignment mark patterned on a sample by a detector and feeding back the alignment mark to an operation of a robot to improve the conveyance accuracy. Further, PTL 2 discloses a configuration in which a vacuum sample chamber and a preliminary exhaust chamber are connected by a bellows, and vibration generated in the preliminary exhaust chamber is removed.

### CITATION LIST

### Patent Literature

PTL 1: JP2004-104021A

PTL 2: JP2023-094309A

### SUMMARY OF INVENTION

### Technical Problem

In PTL 1, since a relative position between the vacuum sample chamber and the preliminary exhaust chamber changes according to a pressure in the preliminary exhaust chamber, in a vacuum processing apparatus that repeatedly opens the preliminary exhaust chamber to an atmosphere and evacuates the preliminary exhaust chamber, the relative position between the preliminary exhaust chamber and the vacuum sample chamber changes each time. That is, a relative position between a sample table provided in the preliminary exhaust chamber, which is the conveyance start position, and the conveyance target position in the vacuum sample chamber changes, and the conveyance accuracy decreases. Therefore, in PTL 1, a measure for ensuring the conveyance accuracy is required.

The method in PTL 2 is effective when the alignment mark is always present at a predetermined position on the sample. However, when the sample wafer without the alignment mark is conveyed, the conveyance error cannot be corrected. In addition, even in a sample wafer provided with the alignment mark, when it is desired to convey the sample after rotating the sample by a desired angle about a rotation axis, it is necessary to increase the number of alignment marks on the sample accordingly, and thus the sample that can be conveyed is limited. In addition, since high positioning accuracy of the conveyance robot is required, a cost of the robot increases, and restrictions on design increase.

The present disclosure has been made in view of the above problems, and an object thereof is to provide a vacuum processing apparatus capable of accurately matching reference coordinates of a sample placement surface of a stage and center coordinates of a sample when a conveyance robot conveys the sample to the sample stage.

### Solution to Problem

A vacuum processing apparatus according to the present disclosure measures a position of an outer edge of a sample conveyed into a vacuum sample chamber, and moves a sample stage below the sample conveyed into the vacuum sample chamber based on the measured position of the outer edge.

### Advantageous Effects of Invention

According to the vacuum processing apparatus of the present disclosure, when a conveyance robot conveys a sample to a sample stage, reference coordinates of a sample placement surface of a stage and center coordinates of the sample can be accurately matched.

### BRIEF DESCRIPTION OF DRAWINGS

FIG. 1 is a schematic top view showing a configuration of a vacuum processing apparatus according to Embodiment 1.

FIG. 2 is a side sectional view of the vacuum processing apparatus.

FIG. 3 is a flowchart showing an operation in which the vacuum processing apparatus according to Embodiment 1 conveys a sample wafer 113.

FIG. 4 is a schematic top view of a vacuum processing apparatus according to Embodiment 2.

FIG. 5 is a side sectional view of the vacuum processing apparatus according to Embodiment 2.

FIG. 6 is a schematic top view of a vacuum processing apparatus according to Embodiment 3.

FIG. 7 is a side sectional view of the vacuum processing apparatus according to Embodiment 3.

FIG. 8 shows an example in which the sample wafer 113 is rectangular.

### DESCRIPTION OF EMBODIMENTS

### Embodiment 1

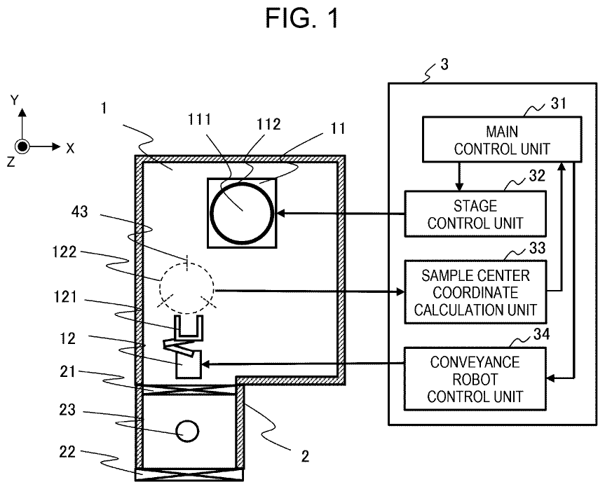

FIG. 1 is a schematic top view showing a configuration of a vacuum processing apparatus according to Embodiment 1 of the present disclosure. The vacuum processing apparatus is an apparatus that processes a sample in a vacuum environment, and is configured as, for example, a charged particle beam apparatus that irradiates the sample with a charged particle beam.

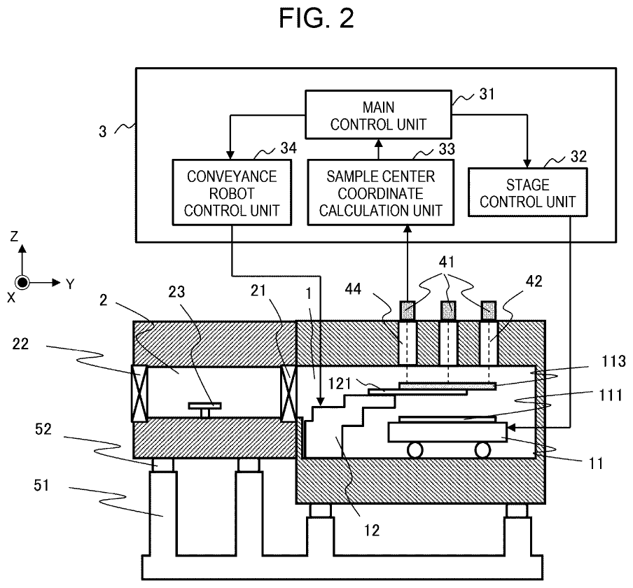

A sample wafer 113 (shown in FIG. 2) is taken out from a FOUP containing the sample wafer 113 by a conveyance robot (not shown). The conveyance robot (not shown) conveys the sample wafer 113 onto a sample table 23 after a door valve 22 of a preliminary exhaust chamber 2 in an atmospheric pressure state is opened. An inside of the preliminary exhaust chamber 2 is evacuated by a vacuum pump (not shown). A vacuum sample chamber 1 is evacuated by the vacuum pump (not shown) and is always kept in a depressurized state. After a pressure in the preliminary exhaust chamber 2 becomes equal to or lower than a threshold, a gate valve 21 is opened, and the sample wafer 113 is conveyed from the preliminary exhaust chamber 2 to the vacuum sample chamber 1 by a conveyance robot 12. The conveyance robot 12 conveys the sample wafer 113 to a conveyance target position 122 in the vacuum sample chamber 1.

The conveyance robot 12 includes a hand 121. The sample wafer 113 is conveyed onto a sample placement surface 111 of a sample stage 11 in a state where the hand 121 holds the sample wafer 113. A ring-shaped electrode 112 is disposed on the sample placement surface 111. It is necessary to convey the sample wafer 113, so that a distance between an outer edge portion of the sample wafer 113 and the electrode 112 becomes a target value.

A detection region 43 is a region for detecting an outer edge position of the sample wafer 113 disposed on the conveyance target position 122 by a detector 41 (shown in FIG. 2). As shown in FIG. 1, the detection region 43 is defined as three or more separated regions. A computer system 3 will be described later.

FIG. 2 is a side sectional view of the vacuum processing apparatus. The door valve 22 seals between the preliminary exhaust chamber 2 and an atmospheric environment. The gate valve 21 seals between the preliminary exhaust chamber 2 and the vacuum sample chamber 1. The sample wafer 113 is placed on the sample table 23 in the preliminary exhaust chamber 2. The vacuum sample chamber 1 and the preliminary exhaust chamber 2 are mounted on a damping mount 52 fixed on a base frame 51.

The conveyance robot 12 receives the sample wafer 113 on the sample table 23, and conveys the sample wafer 113 to the conveyance target position 122 in the vacuum sample chamber 1. The outer edge position of the sample wafer 113 conveyed to the vacuum sample chamber 1 is detected using detection light 42 by the detector 41 provided in the vacuum sample chamber 1. The detector 41 is provided on an upper surface of the vacuum sample chamber 1 on an atmospheric side, and can detect the outer edge position of the sample wafer 113 in the detection region 43 inside the vacuum sample chamber 1 via a transmission window 44 made of a material such as glass that transmits the detection light 42. By disposing the detector 41 outside a vacuum partition wall of the vacuum sample chamber 1, it is possible to prevent a decrease in a degree of vacuum due to emission of a gas from the detector 41 into the vacuum sample chamber 1.

The detector 41 can irradiate the detection region 43 with a plurality of beams of the detection light 42, and the beams of the detection light 42 can detect presence or absence of the sample. When the sample wafer 113 is present at the conveyance target position 122, all of the three or more detection regions 43 include both the outer edge portion of the sample wafer 113 and a region where no sample is present. It is assumed that all of the three or more detection regions 43 include both the outer edge portion of the sample wafer 113 and the region where no sample is present even when an assumed conveyance error occurs.

The sample stage 11 has positioning accuracy higher than required conveyance accuracy. As an example, a position of the sample stage 11 can be specified by a sensor (not shown) such as a laser interferometer provided on an atmosphere side, and the sample stage 11 can be driven by a drive system (not shown) such as a linear motor.

The computer system 3 is a computer that controls the vacuum processing apparatus. The computer system 3 includes a main control unit 31, a stage control unit 32, a sample center coordinate calculation unit 33, and a conveyance robot control unit 34. The main control unit 31 can perform data communication with the stage control unit 32, the sample center coordinate calculation unit 33, and the conveyance robot control unit 34. Operations of these functional units will be described later.

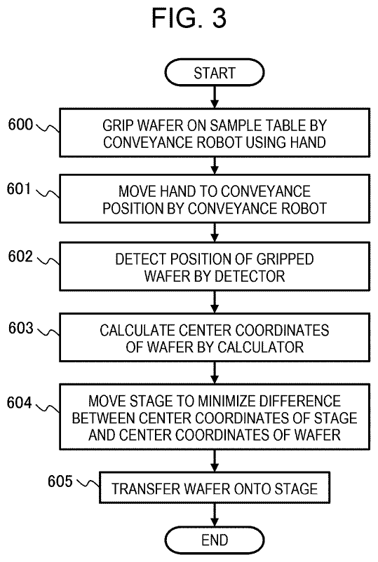

FIG. 3 is a flowchart showing an operation in which the vacuum processing apparatus according to Embodiment 1 conveys the sample wafer 113. The operation based on the flowchart in FIG. 3 is as follows.

Step 600: The conveyance robot control unit 34 issues a command to the conveyance robot 12, and the conveyance robot 12 grips the sample wafer 113 on the sample table 23 using the hand 121 based on the command.

Step 601: The conveyance robot control unit 34 issues a command to the conveyance robot 12, and the conveyance robot 12 moves the hand 121 in a state of gripping the sample wafer 113 to the conveyance target position 122 based on the command.

Step 602: The main control unit 31 simultaneously operates three sets of detectors 41 in the state where the sample wafer 113 is gripped by the hand 121, and acquires information on the presence or absence of the sample in the plurality of detection regions 43 near the outer edge portion of the sample wafer 113. Coordinates at which the presence or absence of the sample is switched are set as coordinates of an end portion of the outer edge portion of the sample wafer 113.

Step 603: The main control unit 31 transmits information on the coordinates of the end portion of the outer edge portion of the sample wafer 113 to the sample center coordinate calculation unit 33. The sample center coordinate calculation unit 33 calculates center coordinates of the sample wafer 113 based on the transmitted information. Hereinafter, a sample center coordinate calculation method in a case of a system including the three sets of detectors 41 will be described.

Step 603: Calculation example: Three sets of coordinates acquired by the detectors 41 are respectively (x1, y1), (x2, y2), and (x3, y3). The sample center coordinate calculation unit 33 substitutes these three sets of coordinates into an equation x\hat{ }2+y\hat{ }2+ax+by+c=0 in which a, b, and c are unknown constants to obtain the following simultaneous equations.

$$x 1 \hat{} 2 + y 1 \hat{} 2 + ax 1 + by 1 + c = 0$$

$$x 2 \hat{} 2 + y 2 \hat{} 2 + ax 2 + by 2 + c = 0$$

$$x 3 \hat{} 2 + y 3 \hat{} 2 + ax 3 + by 3 + c = 0$$

Since there are three sets of equations for three unknown constants, these simultaneous equations can obtain solutions a, b, and c. The sample center coordinate calculation unit 33 obtains solutions a, b, and c by solving the simultaneous equations. Center coordinates (x, y) of the sample have a relationship of (x, y)=(−a/2, −b/2).

Step 604: The obtained center coordinates (x, y) of the sample wafer 113 are transmitted to the main control unit 31. The stage control unit 32 moves the sample stage 11 so as to minimize a distance between reference coordinates of the sample placement surface 111 on the sample stage 11 and the center coordinates of the sample wafer 113.

Step 605: The sample wafer 113 gripped by the hand 121 is transferred to the sample placement surface 111 on the sample stage 11 by using an elevating mechanism provided in the conveyance robot 12 or an elevating mechanism provided in the sample stage 11. By moving the sample stage 11 holding the sample wafer 113 on the sample placement surface 111, desired coordinates of the sample wafer 113 can be measured.

By steps 600 to 605, the reference coordinates of the sample placement surface 111 and the center coordinates of the sample wafer 113 can be matched, and the conveyance accuracy is improved. By improving the conveyance accuracy, a distance between the sample wafer 113 on the sample placement surface 111 and the electrode 112 can be kept within a range of a target value determined by the apparatus, and edge exclusion can be reduced. As a result, a length of a pattern of a semiconductor device chip near an outer edge of the sample wafer 113 can be measured, dimensional control in semiconductor mass production is improved, and a yield is improved.

### Embodiment 1: Summary

In the vacuum processing apparatus according to Embodiment 1, the detector 41 measures the outer edge position of the sample wafer 113 detected in the detection region 43 with respect to the sample wafer 113 conveyed to the conveyance target position 122 in the vacuum sample chamber 1 by the conveyance robot 12. Further, a center position of the sample wafer 113 is calculated based on the measured outer edge position, and the sample stage 11 is moved, so that the center position thereof matches a reference position of the sample stage 11. Accordingly, a positional deviation of the sample wafer 113 due to the conveyance accuracy can be prevented. Therefore, it is possible to correct the conveyance error caused by sliding of a contact portion between the sample and the hand, thermal deformation of a component of the conveyance robot, a change in a relative position between a conveyance start position and the conveyance target position, and the like, and to convey the sample to a position where the distance between the center coordinates of the sample and the reference coordinates of the sample placement surface is minimized. Accordingly, for example, when the vacuum processing apparatus is a charged particle beam inspection apparatus, the distance between the sample and the electrode can be kept within a certain range, a potential of the outer edge portion of the sample and a surface voltage of the sample center portion can be corrected to be equal, an apparatus capable of normally performing a measurement at the outer edge portion of the sample can be implemented, and the edge exclusion can be reduced. Since the apparatus can be mounted even if the sample does not have an alignment mark, Embodiment 1 can be applied to various samples.

### Embodiment 2

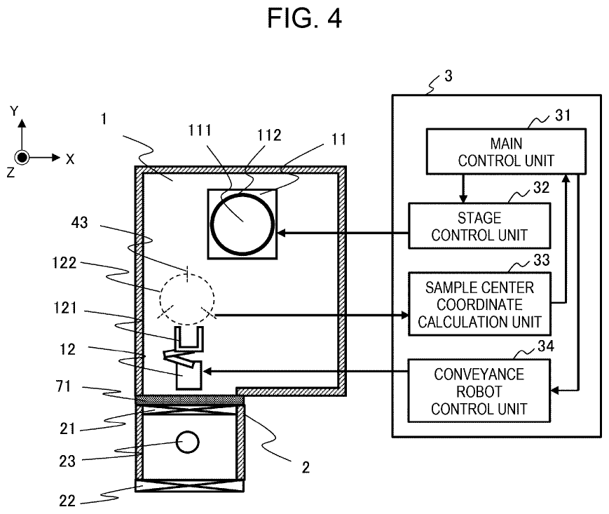

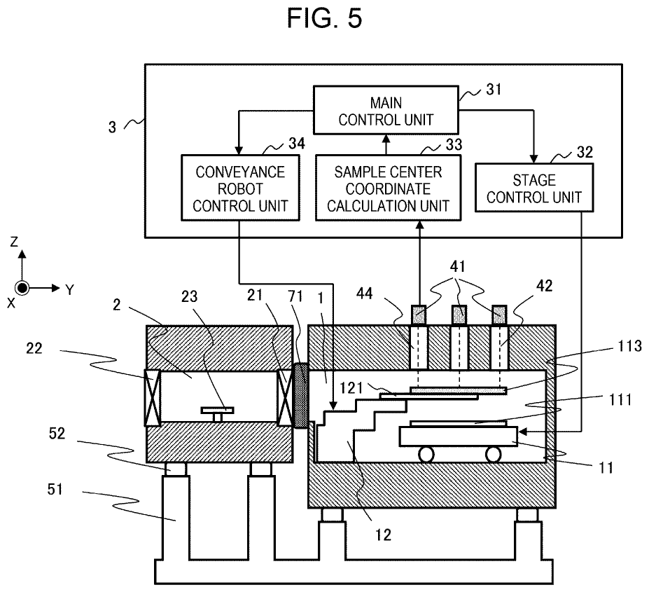

FIG. 4 is a schematic top view of a vacuum processing apparatus according to Embodiment 2 of the present disclosure. FIG. 5 is a side sectional view of the vacuum processing apparatus according to Embodiment 2. The vacuum processing apparatus according to Embodiment 2 includes a bellows 71 between the vacuum sample chamber 1 and the preliminary exhaust chamber 2 in addition to the configuration described in Embodiment 1. The bellows 71 can change a relative position between the vacuum sample chamber 1 and the preliminary exhaust chamber 2. Other configurations are similar to those of Embodiment 1.

The bellows 71 is disposed so as to maintain the vacuum while maintaining the vacuum sample chamber 1 and the preliminary exhaust chamber 2 at the same pressure in a state where the gate valve 21 is open. The bellows 71 has a size that does not interfere with the conveyance robot 12 when the conveyance robot 12 in the state of gripping the sample wafer 113 moves from the preliminary exhaust chamber 2 to the vacuum sample chamber 1. By providing the bellows 71, it is possible to prevent an impact and vibration generated in the preliminary exhaust chamber 2 from being transmitted to the vacuum sample chamber 1, improve measurement accuracy, and improve a throughput by reducing a vibration waiting time.

However, since a relative position between the conveyance robot 12 and the sample table 23 changes when the bellows 71 expands and contracts, positional accuracy when conveying the sample wafer 113 to the conveyance target position 122 may decrease. To solve this problem, in Embodiment 2, even when a relative position between the sample table 23 and the conveyance target position 122 changes, the sample wafer 113 is conveyed after the sample stage 11 is moved with reference to the center coordinates of the sample wafer 113 actually conveyed to the vicinity of the conveyance target position 122. Therefore, the conveyance accuracy can be improved as in Embodiment 1.

### Embodiment 3

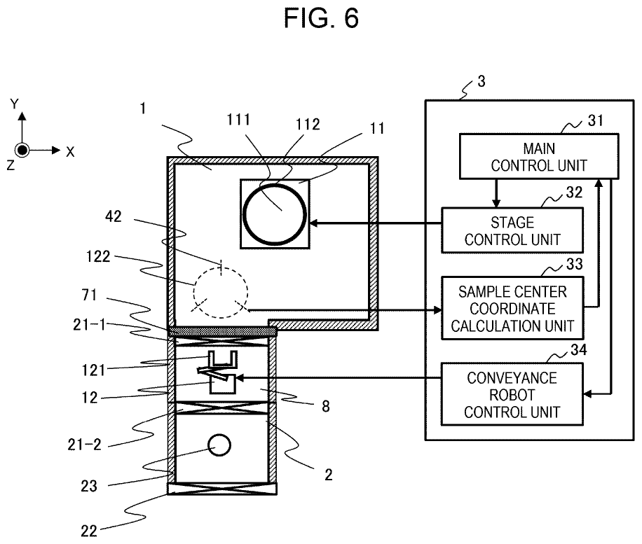

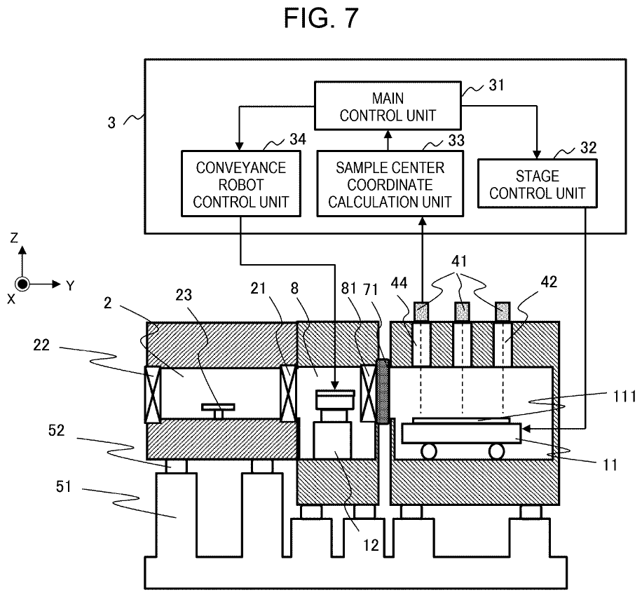

FIG. 6 is a schematic top view of a vacuum processing apparatus according to Embodiment 3 of the present disclosure. FIG. 7 is a side sectional view of the vacuum processing apparatus according to Embodiment 3. In the vacuum processing apparatus according to Embodiment 3, for a purpose of preventing a decrease in the degree of vacuum in the vacuum sample chamber 1, a robot chamber 8 is provided between the preliminary exhaust chamber 2 and the vacuum sample chamber 1, and the conveyance robot 12 is mounted on the robot chamber 8. A gate valve 21-1 is provided between the robot chamber 8 and the vacuum sample chamber 1, a gate valve 21-2 is also provided between the robot chamber 8 and the preliminary exhaust chamber 2, and the bellows 71 is provided between the robot chamber 8 and the preliminary exhaust chamber 2. The bellows 71 is disposed so as to maintain the vacuum while maintaining the vacuum sample chamber 1 and the robot chamber 8 at the same pressure in a state where the gate valve 21-1 is open. The bellows 71 has a size that does not interfere with the conveyance robot 12 when the conveyance robot 12 in the state of gripping the sample wafer 113 moves to the vacuum sample chamber 1. The bellows 71 can change a relative position between the vacuum sample chamber 1 and the robot chamber 8. Other configurations are similar to those in Embodiment 2.

In the configuration of Embodiment 3, since a volume for mounting the conveyance robot 12 can be reduced from an inside of the vacuum sample chamber 1 as compared with Embodiment 2, the vacuum sample chamber 1 can have high exhaust efficiency. In addition, by closing the gate valve 21-1 immediately after the conveyance of the sample by the conveyance robot 12 is completed, it is possible to prevent an adsorption gas adhering to a surface of the conveyance robot 12 from flowing into the vacuum sample chamber 1 and to prevent a decrease in the degree of vacuum. Accordingly, in a charged particle beam inspection apparatus, a convergence rate of the charged particle beam is improved, and the measurement accuracy is improved.

In Embodiment 3, since the relative position between the robot chamber 8 and the vacuum sample chamber 1 changes when the bellows 71 expands and contracts, the positional accuracy when conveying the sample wafer 113 to the conveyance target position 122 may decrease. To solve this problem, in Embodiment 3, since the sample wafer 113 is transferred after the sample stage 11 is moved with reference to a position of the sample wafer 113 actually conveyed to the vicinity of the conveyance target position 122, the conveyance accuracy can be improved as in Embodiment 1.

In Embodiment 3, even when the conveyance robot 12 discharges the gas, an influence of the gas can be prevented by hermetically sealing between the robot chamber 8 and the sample chamber. Further, it is possible to prevent propagation of vibration caused by the conveyance robot 12 to the vacuum sample chamber 1. Further, in Embodiment 3, even when the conveyance target position 122 viewed from the conveyance robot 12 relatively fluctuates, it is possible to prevent a decrease in the conveyance accuracy by detecting the position of the sample wafer 113 in the detection region 43.

### Regarding Modification of Present Disclosure

The disclosure is not limited to the above-described embodiments, and includes various modifications. For example, the above embodiments are described in detail to describe the disclosure in an easy-to-understand manner and are not necessarily limited to including all the described configurations. A part of a configuration of a certain embodiment can be replaced with a configuration of another embodiment, and a configuration of another embodiment can also be added to a configuration of a certain embodiment. In addition, another configuration can be added to a part of a configuration of each embodiment, and the part of the configuration of each embodiment can be deleted or replaced with another configuration.

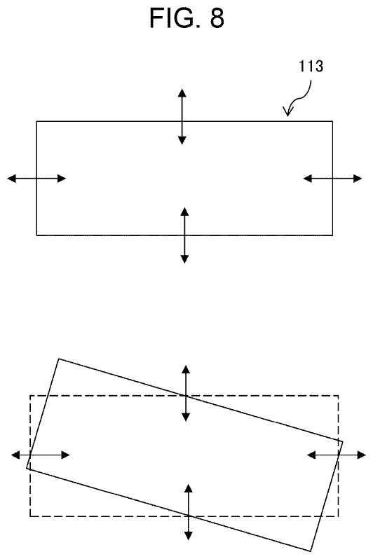

FIG. 8 shows an example in which the sample wafer 113 is rectangular. As shown in an upper part of FIG. 8, it seems that an outer edge portion of a rectangular shape can be specified by performing line scanning on each of four sides. However, as shown in a lower part of FIG. 8, in a case where the sample is rotated in a horizontal plane, when the four sides are detected by the line scanning, a rectangle as indicated by a dotted line in the lower part of FIG. 8 is recognized. The rectangle indicated by the dotted line is different from an actual shape of the sample. That is, in such a case, a correct shape and posture of the sample cannot be recognized. On the other hand, when the sample wafer 113 is circular, a center of the sample can be specified by the line scanning of three or more points even when the sample is rotated in the horizontal plane. Therefore, in the above embodiments, it is assumed that a shape of the sample wafer 113 is a circle. Accordingly, it is assumed that the electrode 112 has a circular shape slightly larger than the sample wafer 113.

In the above embodiments, the main control unit 31, the stage control unit 32, the sample center coordinate calculation unit 33, and the conveyance robot control unit 34 may also be implemented by hardware such as a circuit device on which these functions are mounted, or may also be implemented by an arithmetic device such as a central processing unit (CPU) executing software on which these functions are mounted.

In the above embodiment, the detector 41 is configured as a line sensor that emits the detection light having a line segment shape, but the configuration of the detector 41 is not limited thereto. For example, the detector 41 may be implemented by an image sensor or a camera that images the inside of the vacuum sample chamber 1. That is, a sensor other than the line sensor may be used as long as the center position of the sample wafer 113 in the detection region 43 can be accurately detected.

Although the robot chamber 8 is disposed between the vacuum sample chamber 1 and the preliminary exhaust chamber 2 in the above embodiment, a position of the robot chamber 8 is not limited thereto, and the robot chamber 8 may be disposed, for example, next to the preliminary exhaust chamber 2 in FIG. 1. In this case, the bellows 71 is disposed between the vacuum sample chamber 1 and the preliminary exhaust chamber 2 as in Embodiment 2.

In the above embodiment, it is preferable that the bellows 71 is made of a material capable of preventing the propagation of the vibration to the vacuum sample chamber 1. That is, it is preferable that the material of the bellows has lower rigidity than a housing of the vacuum sample chamber 1 and lower rigidity than a housing of the preliminary exhaust chamber 2.

### REFERENCE SIGNS LIST

1: vacuum sample chamber
11: sample stage
111: sample placement surface
112: electrode
113: sample wafer
12: conveyance robot
121: hand
122: conveyance target position
2: preliminary exhaust chamber
21: gate valve
22: door valve
23: sample table
3: computer system
31: main control unit
32: stage control unit
33: sample center coordinate calculation unit
34: conveyance robot control unit
41: detector
42: detection light
43: detection region
44: transmission window
51: base frame
52: damping mount
71: bellow
8: robot chamber

1. A vacuum processing apparatus comprising:
a vacuum sample chamber configured to process a sample in a vacuum;
a conveyance robot configured to convey the sample in a preliminary exhaust chamber into the vacuum sample chamber;
a detector configured to measure a position of an outer edge of the sample conveyed into the vacuum sample chamber by the conveyance robot;
a stage disposed in the vacuum sample chamber and including a placement surface on which the sample is held; and
a computer configured to control the stage, wherein
the computer moves the stage below the sample conveyed into the vacuum sample chamber based on the measured position of the outer edge.

2. The vacuum processing apparatus according to claim 1, wherein
the conveyance robot conveys the sample to a conveyance target position in the vacuum sample chamber,
the detector is disposed at a position where the position of the outer edge of the sample on the conveyance target position is measurable,
the computer calculates center coordinates of the sample based on the position of the outer edge of the sample on the conveyance target position, and
the computer moves the stage below the sample on the conveyance target position based on the calculated center coordinates.

3. The vacuum processing apparatus according to claim 2, wherein
the detector is disposed to be capable of measuring the position of the outer edge of the sample on the conveyance target position at three or more points, and
the computer calculates the center coordinates based on the position of the outer edge at the three or more points.

4. The vacuum processing apparatus according to claim 1, wherein
the vacuum sample chamber is isolated from an atmospheric environment by a vacuum partition wall,
the detector is attached to the vacuum partition wall on an atmospheric environment side, and
the detector is disposed to measure the sample from above the sample when the sample is conveyed into the vacuum sample chamber.

5. The vacuum processing apparatus according to claim 4, wherein
the detector is configured as a line sensor that detects the position of the outer edge by emitting light having a line segment shape,
the vacuum partition wall includes a transmission portion that transmits at least a part of the light, and
the detector is disposed to emit the light into the vacuum sample chamber via the transmission portion.

6. The vacuum processing apparatus according to claim 2, wherein
the computer moves the stage to match the calculated center coordinates and reference coordinates of a sample placement surface of the stage.

7. The vacuum processing apparatus according to claim 1, wherein
the computer aligns the sample with reference coordinates on the stage based on the measured position of the outer edge by transferring the stage below the sample and then conveying the sample onto the stage.

8. The vacuum processing apparatus according to claim 1, wherein
the sample has a disk shape, and
the detector is configured to be capable of measuring a position on a circular outer periphery of the sample at three or more points.

9. The vacuum processing apparatus according to claim 1, further comprising:
a bellows configured to hermetically join the preliminary exhaust chamber and the vacuum sample chamber, wherein
the bellows is configured to change a relative position between the preliminary exhaust chamber and the vacuum sample chamber, and
the computer moves the stage below the sample based on the position of the outer edge measured by the detector under the relative position.

10. The vacuum processing apparatus according to claim 1, further comprising:
a robot chamber disposed between the vacuum sample chamber and the preliminary exhaust chamber, wherein
the robot chamber stores the conveyance robot, and
the conveyance robot conveys the sample from the preliminary exhaust chamber to the vacuum sample chamber via the robot chamber.

11. The vacuum processing apparatus according to claim 10, further comprising:
a bellows configured to hermetically join the vacuum sample chamber and the robot chamber, wherein
the bellows is configured to change a relative position between the robot chamber and the vacuum sample chamber, and
the computer moves the stage below the sample based on the position of the outer edge measured by the detector under the relative position.

12. The vacuum processing apparatus according to claim 9, wherein
the bellows is made of a material having lower rigidity than the vacuum sample chamber and the preliminary exhaust chamber.

13. The vacuum processing apparatus according to claim 1, wherein
the vacuum processing apparatus is configured as a charged particle beam device that irradiates the sample with a charged particle beam.
